(19) United States
(12) Patent Application Publication
(10) Pub. No.: US 2007/0210315 A1
(43) Pub. Date: Sep. 13, 2007

(54) Semiconductor Device For Emitting Light

(75) Inventors: William Ted Masselink, Berlin (DE); Fariba Hatami, Menlo Park, CA (US)

Correspondence Address: ROTHWELL, FIGG, ERNST & MANBECK, P.C., 1425 K STREET, N.W., SUITE 800, WASHINGTON, DC, 20005, US

(73) Assignee: HUMBOLDT-UNIVERSITAET ZU BERLIN, Berlin (DE)

(21) Appl. No.: 10/574,512

(22) PCT Filed: Sep. 30, 2004
(86) PCT No.: PCT/EP04/11360

§ 371 Date: Oct. 6, 2006

(30) Foreign Application Priority Data
Oct. 2, 2003 (DE) 10347292.4

(51) Int. Cl. H01L 33/00

(52) U.S. Cl. 257/76; 257/E33.001; 977/700

(57) ABSTRACT

A semiconductor device according to the invention for emitting light when a voltage is applied includes a first (3), a second (5) and a third active semiconductor region (7A-7C). While the conductivity of the first semiconductor region (3) is based on charge carriers of a first conductivity type, the conductivity of the second semiconductor region (5) is based on charge carriers of a second conductivity type, which have a charge opposite to the charge carriers of the first conductivity type The active semiconductor region (5 13) is arranged between the first and the second semiconductor regions (3, 5). Embedded in the active semiconductor region (5) are quantum structures (13) which are made from a semiconductor material which has a direct band gap. In that respect the term quantum structures is used to denote structures which in at least one direction of extent are of a dimension which is so small that the properties of the structure are substantially also determined by quantum-mechanical processes.

The present invention concerns a semiconductor device for emitting light when a voltage is applied.

Light-emitting semiconductor devices nowadays represent key components inter alia in devices for transmitting information, in memory devices, in display devices and in lighting devices.

Semiconductor devices which light up in the visible spectral range in contrast do not afford such high levels of light intensity. Thus the first light emitting diodes (LEDs) were able to provide just enough intensity to be used as display elements in early pocket calculators and digital clocks and watches. At the present time however there is a trend for LEDs which light up in the visible spectral region also to be used in areas in which a high level of light intensity is required. For example automobile manufacturers are increasingly seeking to replace conventional lamps in a motor vehicle by LEDs. A further area of use involving LEDs with a high level of light intensity is for example traffic lights in which red, green and amber emitters which provide a very intensive light are required. However it is not only in traffic and vehicle technology but also in information transmission that LEDs which provide a high level of light intensity in the visible spectral range are to be profitably employed. For example LEDs which highly intensively emit light in the visible spectral range can be used for short-range data transfer by way of plastic fibers. In contrast to glass fibers in which maximum transmission, that is to say maximum transmissivity for electromagnetic radiation, is in the infrared spectral range, the maximum transmission in the case of plastic fibers is in the green spectral range so that in particular LEDs emitting highly intensively green light are of interest for data transfer by way of plastic fibers. In that respect, what is important for the specified areas of use are both the efficiency of the radiation-generation process in the semiconductor material, as that is of significance in terms of the intensity of the radiation delivered, and also the wavelength of the radiation delivered.

The electrical behaviour of a semiconductor material can be described with what is referred to as the band model. That states that various energy ranges, referred to as the energy bands, are available to the charge carriers of the semiconductor material, within which they can assume substantially any energy values. Different bands are frequently separated from each other by a band gap, that is to say an energy range involving energy values which the charge carriers cannot assume. If a charge carrier moves from an energy band at a higher energy level into an energy band at a low energy level, energy is liberated, which corresponds to the differences of the energy values prior to and after the movement. In that case the difference energy can be liberated in the form of light quanta (photons). A distinction is drawn between what are referred to as direct and indirect band gaps. In the case of an indirect band gap, two processes must coincide so that a transition between the energy bands can take place, with the emission of light. Accordingly semiconductor materials with energy band gaps generally involve a much lower degree of efficiency when producing light than semiconductor materials with what are referred to as direct band gaps in which only one process is necessary for the emission of light.

In a semiconductor material negatively charged electrons and positively charged holes which can be imagined essentially as ‘missing’ electrons in an energy band are available as charge carriers. A hole can be filled by the transition of an electron from another energy band into the energy band in which the hole is present. The process of filling a hole is referred to as recombination. By introducing impurities, referred to as dopants, into the semiconductor material, it is possible to produce a predominance of electrons or holes as charge carriers. When there is a predominance of electrodes, the semiconductor material is referred to as n-conducting or n-doped while when there is a predominance of holes as charge carriers it is referred to as p-conducting or p-doped. In addition the introduction of dopants can be used to influence the energy levels available to the charge carriers in the semiconductor material.

Nowadays many commercially available LEDs are based on gallium phosphide (GaP) which is a semiconductor material with an indirect band gap. The introduction of what are referred to as deep impurities which can be envisaged in simplified fashion as energy levels accessible to the charge carriers outside the energy bands of the GaP permits the production of GaP-based LEDs. The efficiency of LEDs of that kind in the production of light is low because of the indirect band gap. The deep impurities can be produced by impurity atoms such as for example nitrogen atoms being suitably introduced into the GaP.

LEDs which are based on GaP which is doped with nitrogen (N), that is to say into which nitrogen is introduced as a dopant, emit in the spectral range of green to yellow in dependence on the amount of N with which it is doped.

LEDs which are based on GaP doped with zinc oxide (ZnO) in contrast emit red light. Admittedly ZnO-doped GaP, in comparison with N-doped GaP, enjoys a somewhat higher level of efficiency when producing light, but the emission takes place in a spectral frequency range in which the human eye is relatively insensitive so that the emitted light appears less bright. In addition the efficiency of the light-production process decreases in ZnO-doped GaP, with an increasing control current for the LED.

The object of the present invention is to provide a light-emitting semiconductor device which has a high level of efficiency upon emitting light in particular in the visible spectral range.

That object is attained by a light-emitting semiconductor device as set forth in claim 1. The appendant claims set forth advantageous configurations of the invention.

A semiconductor device according to the invention for emitting light when a voltage is applied includes a first, a second and a third active semiconductor region. The first and the second semiconductor regions can each include in particular AlₓGa₁₋ₓP (aluminum gallium phosphide) with 0≦x≦1. While the conductivity of the first semiconductor region is based on charge carriers of a first conductivity type the conductivity of the second semiconductor region is based on charge carriers of a second conductivity type, which have a charge opposite to the charge carriers of the first conductivity type. Arranged between the first and second semiconductor regions is the active semiconductor region which can include in particular AlₓGa₁₋ₓP with 0≦x≦1, wherein embedded in the active semiconductor region are quantum structures which are made from a semiconductor material which has a direct band gap. In that case the AlₓGa₁₋ₓP of all semiconductor regions may also contain a small proportion of arsenic (As) (up to about 50%) which is not further mentioned here but which is intended also to be embraced by the designation AlₓGa₁₋ₓP.

In that respect the term quantum structures is used to denote structures which in at least one direction of extent are of a dimension which is so small that the properties of the structure are substantially also determined by quantum-mechanical processes. The quantum structures involved can be for example quantum dots in which all directions of extent are of small dimensions, quantum wires in which two directions of extent are of small dimensions or quantum wells in which one direction of extent is of small dimensions.

The semiconductor material from which the quantum structures are made can be in particular a III-V semiconductor material, that is to say a compound of elements from the 3rd and 5th groups of the periodic system, which has a direct band gap and a lattice constant which is greater than that of GaP. It is to be noted in that respect that the lattice constant of AlₓGa₁₋ₓP does not depend on x and is of substantially the same value as GaP. A suitable III-V semiconductor material is for example InP (indium phosphide) but other compounds of elements of the 3rd group such as for example indium (In), gallium (Ga) or aluminum (Al) with elements from the 5th group such as for example phosphorus (P), arsenic (As) or antimony (Sb) are also fundamentally suitable.

With the semiconductor structure according to the invention for the emission of light, when a voltage is applied, a higher level of efficiency can be achieved in the visible spectral range when emitting light than with light-emitting semiconductor structures in accordance with the state of the art. The reason for this is as follows:

In contrast to the GaP-based, light-emitting semiconductor devices in accordance with the state of the art, the semiconductor device according to the invention makes it possible to use a direct transition between two energy bands for emitting light in the visible spectral range. In that case the direct transition takes place in the embedded quantum structures, that is to say for example in the InP which has a direct band gap. As mentioned hereinbefore, the efficiency when emitting light with a direct transition is higher than in the case of an indirect transition so that the efficiency of the semiconductor device according to the invention for emitting light when a voltage is applied is higher than that of light-emitting semiconductor devices in accordance with the state of the art.

In addition in production of the semiconductor device according to the invention it is possible in part to have recourse to the technology of LEDs based on GaP.

In an advantageous configuration of the semiconductor device according to the invention the semiconductor regions are embodied in the form of semiconductor layers of a layer stack. In that case epitaxial processes which are known from semiconductor technology can be used for producing the semiconductor device. In that respect the term epitaxial processes is used to denote all processes with which a layer can be applied in ordered fashion to a crystalline substrate. Molecular beam epitaxy (MBE) and deposition from the gaseous phase (chemical vapor deposition or CVD) may be mentioned as examples here. With the epitaxial process, the bonding of wafers, that is to say securing wafers together by adhesive means, which is involved when producing LEDs based on AlGaInP or GaP, is not necessary. Therefore the production in particular of semiconductor devices according to the invention in the form of LEDs is simplified in comparison with LEDs in accordance with the state of the art. Furthermore the epitaxial process can be well integrated into existing process procedures for the production of semiconductor devices. The occurrence of defects in the semiconductor regions can also be reduced by the use of the epitaxial processes. Such defects would adversely influence the emission properties of the semiconductor device.

The existence of a direct transition is ensured in the semiconductor device according to the invention in particular when the quantum structures involve a lateral extent, that is to say an extent in perpendicular relationship to the stack direction, which on average is less than about 50 nm. In particular the average lateral extent of the quantum structures is in the range of between 10 and 30 nm.

In particular if the InP coverage is at least 0.5 monolayer (ML), emission takes place in the visible spectral range. In that respect a monolayer corresponds to a coverage which, with uniform distribution of the InP over the layer under the quantum structures, would give an InP layer which is monoatomic in the stack direction. In particular the InP coverage can be between 0.5 mL and about 10 mL, preferably between 0.5 and 8 mL and in particular between 0.5 mL and about 4 mL. The color of the emitted light can be established by a suitable selection of the coverage within the specified limits.

In an advantageous development of the semiconductor device according to the invention the active semiconductor region includes a plurality of sub-regions which have different InP coverages. Suitably selecting the respective coverage of the sub-regions makes it possible to produce a semiconductor device which delivers virtually white light. In that case the sub-regions can in particular be in the form of various semiconductor layers. Alternatively, instead of that, they can also be distinguished in respect of their lateral arrangement so that they form various partial regions of a common semiconductor layer.

The semiconductor device according to the invention can be in particular in the form of a light-emitting diode, a superluminescent diode or a laser diode. In the case of the superluminescent diode or the laser diode the semiconductor device according to the invention forms the active region of the superluminescent diode or the laser diode and the immediately adjoining regions. Superluminescent diodes and in particular laser diodes cannot be implemented by means of the deep impurities known from the state of the art.

Further features, properties and advantages of the semiconductor device according to the invention will be apparent from the description hereinafter of an embodiment of the invention, with reference to the accompanying drawings.

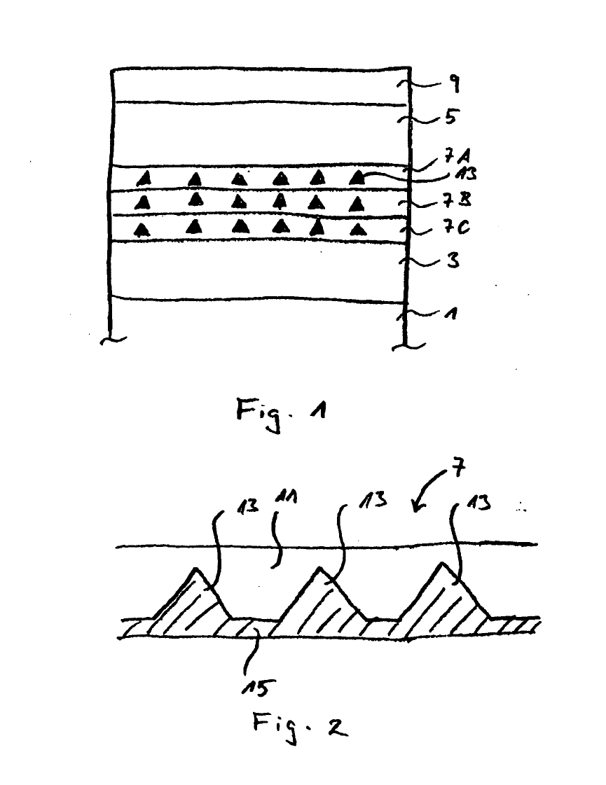

FIG. 1 diagrammatically shows a layer stack implementing the invention, and

FIG. 2 shows a view in detail of a portion from the active semiconductor region of the semiconductor device structure according to the invention.

FIG. 1 as an embodiment of the semiconductor device according to the invention represents the layer stack of a light emitting diode which is disposed on an n-doped substrate 1. The layer stack includes an n-doped first semiconductor layer 3 which forms a first semiconductor region and a p-doped second semiconductor layer 5 which forms a second semiconductor region. In this respect in the present embodiment the electrons of the n-doped first semiconductor layer 3 represent the charge carriers of the first conductivity type whereas the holes of the p-doped second semiconductor layer 5 represent the charge carriers of the second conductivity type. Arranged between the n-doped first semiconductor layer 3 and the p-doped second semiconductor layer 5 are three undoped quantum structure layers 7A-7C which form the active semiconductor region of the LED. Admittedly in the present embodiment the quantum structure layers 7A-7C are undoped but in alternative configurations of the embodiment they can also have an n-doping or a p-doping. Finally disposed over the second semiconductor layer 5 is a heavily p-doped contact layer 9 for electrically contacting the second semiconductor layer 5.

It should be noted that the dopings of the substrate 1, the first and second semiconductor layers 3, 5 and the contact layer 9 can also be reversed. The semiconductor structure according to the invention would then have a p-doped substrate, a p-doped first semiconductor layer 3, an n-doped second semiconductor layer 5 and an n-doped contact layer 9.

The layer thicknesses are not shown to scale in FIG. 1. While the semiconductor layer 3 is of a thickness of 100 nm and the semiconductor layer 5 is of a thickness of 700 nm, the three quantum structure layers 7A-7C together involve only a thickness of about 9 nm and the contact layer 9 is of a layer thickness of 10 nm.

The substrate 1, the first semiconductor layer 3, the second semiconductor layer 5 and the contact layer 9 are in the form of doped GaP layers. The substrate 1 and the first semiconductor layer 3 each contain silicon (Si) as the dopant, wherein the Si-concentration in the first semiconductor layer 3 corresponds to 5×10¹⁷ cm⁻³. The second semiconductor layer 5 and the contact layer 9 in contrast contain beryllium (Be) as dopant, more specifically in a concentration of 5×10¹⁷ cm⁻³ (second semiconductor layer 5) and 1×10¹⁹ cm⁻³ (contact layer 9) respectively.

One of the quantum structure layers 7A-7C is shown in detail in FIG. 2. The quantum structure layer 7 includes a GaP layer 11 in which InP islands 13 are embedded, as quantum dots. The GaP layer 11 is sometimes also referred to as the GaP matrix. The InP islands are placed on what is referred to as an InP wetting layer 15 which covers the entire surface of the layer disposed under the quantum structure layer 7, and is of a thickness of between 0.1 and 0.3 nm. The thickness of the GaP layer 11 is so selected that the InP islands 13 are still covered with GaP, but at a maximum with about 1 nm GaP. In total the thickness of the quantum structure layer 7 shown in FIG. 2 is about 3 nm.

The lateral dimensions of the InP islands 13 are on average a maximum of about 50 nm. Preferably the average of the lateral dimensions is in the range of between 10 and 30 nm and the coverage of the layer under the quantum layer structure 7 by the InP is about 3.5 ml, that is to say the InP would suffice to cover over the layer therebeneath with about 3.5 monoatomic InP layers. In that respect about 1 ml of the InP is allotted to the wetting layer. In the present embodiment that coverage results in the emission of light at a wavelength of about 600 nm. By varying the InP coverage it is possible to implement light emitting diodes which give off light in the spectral range between orange and green.

With a coverage of about 1.8 ml or less, there are no longer any InP islands. Instead the InP forms a uniform layer so that a quantum layer is produced, instead of quantum dots. When reference is made to quantum dots in the present embodiment, that is also intended to embrace coverages below 1.8 ml without reference being made expressly to quantum layers instead of to quantum dots.

In the present embodiment three quantum structure layers 7A-7C are arranged between the first and second semiconductor layers 3, 5. It is sufficient however if there is one such quantum structure layer 7. On the other hand however there can also be more than only three quantum structure layers. Preferably there are three to five quantum structure layers.

Together with the quantum structure layers 7A-7C, the first and the second semiconductor layers 3, 5 form a light emitting diode. Therein, with a voltage which is suitably applied between the contact layer 9 and the substrate 1 and which is generally referred to as the forward voltage, electrons pass from the first semiconductor layer 3 and holes pass from the second semiconductor layer 5 into the quantum structure layers 7A-7C. Recombination of electrons and holes takes place in the quantum structure layers 7A-7C, that is to say the electrons fill the holes. In regard to the electrons that recombination represents a transition from an energy band at a higher energy level into an energy band at a lower energy level. In that respect the transition is a direct transition which takes place substantially in the quantum dots, that is to say in the InP. By virtue of the small dimensions of the InP quantum dots the band gap in the InP is much larger than in a large-volume InP material so that the wavelength of the light emitted in the direct transition is in the visible spectral range. As the band gap in the InP quantum dots, that is to say the minimum spacing in respect of energy between the two bands and thus the wavelength of the emitted light, depends on the InP coverage, the color of the emitted light can be varied in the range of orange to green by a suitable selection of the InP coverage.

Admittedly, in the described embodiment the substrate 1, the first semiconductor layer 3, the second semiconductor layer 5 and the contact layer 9 are described as GaP layers, but those layers can generally also be in the form of AlₓGa₁₋ₓP layers with 0≦x≦1, wherein the values for x can be different from one layer to another. In a corresponding manner the quantum structures do not need to be made from InP. Instead they can be in the form of In_{y}Ga_{1-y}P layers with 0≦y≦0.5, preferably 0≦y≦0.1. As AlₓGa₁₋ₓP is transparent in the visible spectral range the described layer structure can also be used in particular to produce LEDs which emit vertically, that is to say in the stack direction.

By means of suitable measures for enclosing the emitted light in the active region of the semiconductor device, for example by a suitable choice in respect of the refractive index of the individual layers or by the provision of facets at the semiconductor structure, it is possible to produce superluminescent diodes emitting incoherent light or laser diodes emitting coherent light, with the semiconductor device according to the invention. The fundamental structure of superluminescent diodes and laser diodes is to be found for example in the books ‘Spontaneous Emission and Laser Oscillation in Microcavities’, Edit. by Hiroyuki Yokoyama and Kikuo Ujihara, CRC Press (1995)’ and ‘Optoelectronics: An Introduction to Material and Devices’, Jasprit Singh, The McGraw-Hill Companies, Inc (1996)’ to which reference is directed in respect of the further configuration of the superluminescent diode according to the invention and the laser diode according to the invention.

1. A semiconductor device for emitting light when a voltage is applied comprising
a first semiconductor region (3) whose conductivity is based on charge carriers of a first conductivity type,
a second semiconductor region (5) whose conductivity is based on the charge carriers of a second semiconductor type, which have a charge opposite to the charge carriers of the first conductivity type, and
an active semiconductor region (7A-7C) which is arranged between the first semiconductor region (3) and the second semiconductor region (5) and in which quantum structures (13) of a semiconductor material with a direct band gap are embedded.

2. A semiconductor device as set forth in claim 1 wherein the first semiconductor region (3), the second semiconductor region (5) and the active semiconductor region (7A-7C) each include AlₓGa₁₋ₓP with 0≦x≦1 and the quantum structures (13) are made from a III-V semiconductor material having a lattice constant which is greater than that of GaP.

3. A semiconductor device as set forth in claim 2 wherein the III-V semiconductor material includes InP.

4. A semiconductor device as set forth in claim 1, wherein the semiconductor regions are embodied in the form of semiconductor layers (3, 5, 7A-7C) of a layer stack.

5. A semiconductor device as set forth in claim 1 wherein the quantum structures (13) are of a lateral extent which on average is less than about 50 nm.

6. A semiconductor device as set forth in claim 5 wherein the average lateral extent of the quantum structures (13) is in the range of between 10 and 30 nm.

7. A semiconductor device as set forth in claim 3, wherein the InP coverage is at least 0.5 mL.

8. A semiconductor device as set forth in claim 7 characterised in that the active semiconductor region (7A-7C) includes a plurality of sub-regions which have different InP coverages.

9. A light emitting diode comprising a semiconductor device as set forth in claim 1.

10. A superluminescent diode comprising a semiconductor device as set forth in claim 1.

11. A laser diode comprising a semiconductor device as set forth in claim 1.
